(19) United States
(12) Patent Application Publication
(10) Pub. No.: US 2007/0175510 A1
(43) Pub. Date: Aug. 2, 2007

(54) Photoelectric conversion apparatus and gelling agent

(75) Inventors: Masahiro Morooka, Kanagawa (JP); Yusuke Suzuki, Kanagawa (JP); Reiko Ogura, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 11/699,186

(22) Filed: Jan. 29, 2007

(30) Foreign Application Priority Data
Jan. 30, 2006 (JP) JP2006-020306

(51) Int. Cl. H01L 31/00

(52) U.S. Cl. 136/263

(57) ABSTRACT

A photoelectric conversion apparatus is provided. The photoelectric conversion apparatus includes an electrolyte layer interposed between a semiconductor layer and a counter electrode. The electrolyte layer includes an electrolyte solution retained in a fibrous inorganic matrix in a gel state.

### CROSS REFERENCE TO RELATED APPLICATION

The present invention contains subject matter related to Japanese Patent Application JP 2006-020306 filed in the Japanese Patent Office on Jan. 30, 2006, the entire contents of which being incorporated herein by reference.

### BACKGROUND OF THE INVENTION

1. Field of the Invention

The present invention relates to a photoelectric conversion apparatus capable of being used as, for example, a solar cell and, more particularly, to a photoelectric conversion apparatus capable of being utilized as, for example, a dye-sensitized photoelectric conversion apparatus free from an anxiety that an electrolyte solution may be leaked.

2. Description of the Related Art

When a fossil fuel such as coal or petroleum is used as an energy source, there is a concern about an atmospheric warming to be caused by the resultant carbon dioxide. Further, when atomic energy is utilized, there are a difficulty of controlling nuclear fission, a risk of radiation contamination due to generated radioactive elements and the like. At the present day in which a global environment conservation has become an important issue, there are many problems in continuously depending on these energy sources.

A solar cell utilizing sunlight is receiving attention as an energy source that can substitute for the fossil fuel, and various types of studies have been exerted. The solar cell is one type of photoelectric conversion apparatus which can convert light energy into electric energy. Since the solar cell utilizes sunlight as an energy source, it gives an extremely small influence to a global environment and is expected to be more widely distributed.

Various types of studies have been exerted on theories and materials for the solar cell. Above all, at present, the solar cell which utilizes a pn junction of a semiconductor is most widely distributed and a number of solar cells which each use silicon as a semiconductor material are commercially available. These solar cells are roughly classified into crystalline silicon-type solar cells which each use single crystal silicon or polycrystal silicon and amorphous silicon-type solar cells which each use amorphous silicon.

Since photoelectric conversion efficiency, which exhibits performance of converting the light energy of sunlight to the electric energy, of the crystalline silicon-type solar cell is higher than that of the amorphous silicon-type solar cell, a number of crystalline silicon-type solar cells have so far been used as the solar cells. However, sine the crystalline silicon-type solar cells need much energy and time for crystal growth, productivity thereof is low and, then, cost thereof comes to be high.

On the other hand, the amorphous silicon-type solar cell is advantageous in that the amorphous silicon-type solar cell can absorb and, then, utilize light having a wider range of wavelength than that of the crystalline silicon-type solar cell and can select various types of substrate materials having respective material qualities, to thereby easily expand a surface area thereof. Further, since there is no need of crystallization, the amorphous silicon-type solar cell can be produced at low cost with high productivity compared with the crystalline silicon-type solar cell. However, the photoelectric conversion efficiency of the amorphous silicon-type solar cell is lower than that of the crystalline silicon-type solar cell.

In any type of the silicon-type solar cells, since it is necessary to conduct a step of producing a semiconductor material of high purity or a step of forming the pn junction, there is a problem in that the producing steps become large in number or, since it is necessary to conduct a producing step in a vacuum condition, there is a problem in that production equipment cost and energy cost become high.

In order to realize a solar cell having no such problems as described above and capable of being produced at lower cost, many solar cells using organic materials in place of silicon-type materials have long been studied. However, many of them each had a photoelectric conversion efficiency of as low as 1% or less and also had a problem in durability.

On the other hand, a dye-sensitized photochemical cell (photoelectric conversion apparatus) which utilized a light-excited electron transfer sensitized by a dye was proposed in 1991 (refer to, for example, Japanese Patent No. 2664194, pp 2 and 3, FIG. 1 and B. O'Regan and M. Graetzel, Nature, Vol. 353, pp 737 to 740 (1991)). Since this photoelectric conversion apparatus has a high photoelectric conversion efficiency, it needs not install such large-scale production equipment as vacuum devices, and can conveniently be produced with favorable productivity by using an inexpensive material such as titanium oxide, this photoelectric conversion apparatus is expected to be the solar cell of new generation.

FIG. 3 is a cross-sectional view of a major portion of a configuration of an ordinary dye-sensitized photoelectric conversion apparatus 100 in related art. The dye-sensitized photoelectric conversion apparatus 100 is configured by mainly containing a transparent substrate 1 such as glass, a transparent electrode (negative electrode) 2 containing a transparent conductive layer of, for example, FTO (fluorine-doped tin oxide (IV) SnO₂), a semiconductor layer 3 retaining a photosensitizing dye, an electrolyte layer 104, a counter electrode (positive electrode) 5, a counter substrate 6, and a sealing material (not shown) and the like.

As for the semiconductor layer 3, a porous article layer prepared by sintering fine particles of titanium oxide TiO₂ is used in many cases. On surfaces of the fine particles of titanium oxide TiO₂ which are contained in the semiconductor layer 3, a photosensitizing dye is retained. The electrolyte layer 104 is filled between the semiconductor layer 3 and the counter electrode 5 and, for example, an organic electrolyte solution containing oxidation-reduction species (redox pair) such as I⁻/I₃⁻ is used in the electrolyte layer 104. The counter electrode 5, which is made of a platinum layer 5b or the like, is formed on the counter substrate 6.

When light is incident on the dye-sensitized photoelectric conversion apparatus 100, it operates as a cell in which the counter electrode 5 is a positive electrode and the transparent electrode 2 is a negative electrode. A theory of such operation is as described below.

When the photosensitizing dye absorbs a photon which passes through the transparent substrate 1 and the transparent electrode 2, an electron inside the photosensitizing dye is excited to undergo transition from a ground state (HOMO) to an excited state (LUMO). The electron in the excited state is drawn out into a conduction band of the semiconductor layer 3 via an electric bond between the photosensitizing dye and the semiconductor layer 3, passes through the semiconductor layer 3 and, then, reaches the transparent electrode 2.

On the other hand, the photosensitizing dye which has lost the electron receives an electron from a reducing agent, for example, an iodide ion (I⁻), in the electrolyte layer 104 in accordance with the following reaction and, accordingly, generates an oxidizing agent, for example, a triiodide ion (I₃⁻) (combined body of I₂ and I⁻), in the electrolyte layer 104:

2I⁻→I₂+2e⁻

I₂+I⁻→I₃⁻

The thus-generated oxidizing agent reaches the counter electrode 5 by diffusion and, then, receives an electron from the counter electrode 5 in accordance with the following reaction which is reverse to the above-described reaction and is, accordingly, reduced to an original reducing agent:

I₃⁻→I₂+I⁻

I₂+2e⁻→2I⁻

The electron which is sent out from the transparent electrode 2 to an outside circuit performs an electric work in the outside circuit and, then, returns to the counter electrode 5. In such a manner as described above, light energy is converted into electric energy without leaving any change in each of the photosensitizing dye and the electrolyte layer 104.

Ordinarily, in order to effectively operate the photoelectric conversion apparatus, it is important to enhance light absorption efficiency such that light incident on the photoelectric conversion apparatus can be used to the maximum. In the dye-sensitized photoelectric conversion apparatus, since light absorption is borne by the photosensitizing dye and, accordingly, it is expected that a maximum light absorption rate can be attained by selecting a photosensitizing dye having an optimal light absorption characteristic against incident light. In order to realize a high light absorption rate at the time of utilizing it as the solar cell, it is desirable to select a photosensitizing dye capable of effectively absorbing light having a wavelength of from 300 to 900 nm in the vicinity of a visible light region and, on this occasion, for example, a ruthenium complex is used.

Now, since the dye-sensitized photoelectric conversion apparatus 100 is a wet-type photoelectric conversion apparatus using the electrolyte layer 104 in liquid form, in order to enhance safety and durability, it is necessary to solve a problem of leakage of a solution. One method of solving the problem is a method of gelling the electrolyte solution.

In the past, as for methods for gelling the electrolyte solution, for example, a method for forming a physical gel by gelling the electrolyte solution by means of crystallizing a polymer therein, a method for forming a chemically cross-linked gel by gelling the electrolyte solution by means of chemically cross-linking a polymer therein, and a method for forming a nanocomposite gel by gelling the electrolyte solution by means of dispersing fine particles of an oxide, or a nano-material such as a carbon nanotube are mentioned (refer to YANAGIDA Shozo, et al., Fujikura technical report, “Nanoconpojitto ion geru o mochiita shikiso zokan taiyodenchi (Dye-sensitized solar cell using nanocomposite ion gel)”, Vol. 107, pp. 73 to 78 (October, 2004)). Among these methods, the method for forming the nanocomposite gel is capable of forming a gel only by mixing an electrolyte solution and a gelling agent with each other and is also capable of infiltrate the electrolyte solution into a titanium oxide porous layer having a semiconductor layer 3 by coating the semiconductor layer 3 with the electrolyte in a gel state.

### SUMMARY OF THE INVENTION

However, in an electrolyte in a gel state forming a nanocomposite gel, a ratio in which an electrically inactive gelling agent is contained in the gel is large, compared with a gel using a polymer and, as a result, there is a problem in that an inner resistance in the photoelectric conversion apparatus is increased and a fill factor and photoelectric conversion efficiency are decreased.

The fill factor is also called as a form factor and is one of parameters which show characteristics of the photoelectric conversion apparatus. In a current-voltage curve of the ideal photoelectric conversion apparatus, a given output voltage having a same intense as that of release voltage is maintained until output current comes to have same extent as that of short-circuit current but, since current-voltage curve of an actual photoelectric conversion apparatus has an inner impedance, it goes off an ideal current-voltage curve. A ratio of an area of a region enclosed by an actual current-voltage curve and an x axis and a y axis to a rectangular area of a region enclosed by the ideal current-voltage curve and an x axis and a y axis is called as the fill factor. The fill factor exhibits an extent of deviance from the ideal current-voltage curve and, as the value of the fill factor comes nearer to 1, the current-voltage curve comes nearer to the ideal current-voltage curve and, accordingly, the rate of the photoelectric conversion becomes higher.

In an electrochemical apparatus having a gelled electrolyte, ordinarily, there is a tendency in which, as a ratio of the gelling agent to be added is larger, the inner impedance becomes larger. On the other hand, as described above, in the photoelectric conversion apparatus, the fill factor varies depending on the inner impedance of the photoelectric conversion apparatus, is decreased more as the inner impedance is increased more and is deviated more from 1. For this account, an increase of the gelling agent brings about a decrease of the fill factor, namely, a decrease of photoelectric conversion performance.

Under these circumstances, it is desirable to provide a photoelectric conversion apparatus capable of being utilized as a dye-sensitized photoelectric conversion apparatus, having an electrolyte in a gel state free from an anxiety that an electrolyte solution may be leaked, in which a decrease of a fill factor to be caused by gelling of the electrolyte is small, and a gelling agent.

Namely, an embodiment of the present invention relates to a photoelectric conversion apparatus, having an electrolyte layer interposed between a semiconductor layer and a counter electrode, in which the electrolyte layer contains an electrolyte solution retained in a fibrous inorganic matrix in a gel state. Another embodiment of the invention relates to a gelling agent containing a fibrous inorganic matrix material.

Further, the term “matrix” used herein indicates a solid component in a gel which is a configuration forming a three-dimensional structure with many spaces therein and having a function capable of retaining a liquid in these spaces.

Since the gelling agent according to an embodiment of the invention contains a fibrous inorganic matrix material, the gelling agent has a large specific surface area and a high performance of retaining the electrolyte. For this account, since the electrolyte can be gelled with a small amount of the gelling agent, when the electrolyte in a gel state is formed, a ratio of the matrix material to be contained in the electrolyte in a gel state can be reduced and, as a result, an increase of the inner impedance of the photoelectric conversion apparatus can be suppressed to a small extent.

In the photoelectric conversion apparatus according to an embodiment of the invention, since the electrolyte is gelled by using the gelling agent, the high-safety photoelectric conversion apparatus free from an anxiety that the electrolyte may be leaked can be realized and the increase of the inner impedance in the photoelectric conversion apparatus can be suppressed to a small extent, and a decrease of the fill factor, namely, a decrease of a photoelectric conversion performance can be suppressed to a small extent.

### BRIEF DESCRIPTION OF THE DRAWINGS

FIG. 1 is a cross-sectional view of a major portion of a configuration of a dye-sensitized photoelectric conversion apparatus according to an embodiment of the present invention;

FIG. 2 is an electron micrograph of titanium oxide-type nanowire according to an embodiment of the present invention; and

FIG. 3 a cross-sectional view of a major portion of a configuration of an ordinary dye-sensitized photoelectric conversion apparatus in related art.

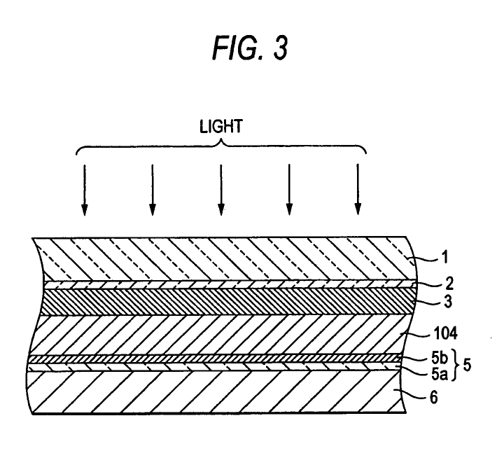

### DESCRIPTION OF THE PREFERRED EMBODIMENTS

In a photoelectric conversion apparatus according to an embodiment of the present invention, an inorganic matrix preferably contains an inorganic matrix material obtained by subjecting fine particles of a metal oxide to a hydrothermal reaction treatment under a strong alkali having a pH value of 10 or more. On this occasion, the metal oxide is titanium oxide, the hydrothermal reaction treatment is preferably conducted in an aqueous solution containing at least one type of a base selected from the group consisting of lithium hydroxide LiOH, sodium hydroxide NaOH, and potassium hydroxide KOH and such reaction may be performed under pressure, as need arises.

Further, the photoelectric conversion apparatus according to another embodiment of the invention is preferably a dye-sensitized photoelectric conversion apparatus in which a photosensitizing dye is retained in the semiconductor layer, an electron of the photosensitizing dye excited by absorbing light is drawn out into the semiconductor layer, and the photosensitizing dye which has lost the electron is reduced by a reducing agent in the electrolyte layer.

In a gelling agent according to an embodiment of the invention, the inorganic matrix material preferably contains a crystalline nano-material. For example, a composition of the inorganic matrix material is preferably represented by the general formula, (M,H)ₓTi_{y}O_{z}, (in which M represents at least one alkali metal element selected from the group consisting of lithium Li, sodium Na, and potassium K, and x, y, and z each represent a positive number). On this occasion, a diameter of the fibrous crystalline nano-material is preferably in the range of from 2 to 80 nm and length thereof is preferably 100 nm or more (refer to JP-A-2005-162584).

Hereinafter, a photoelectric conversion apparatus configured as a dye-sensitized photoelectric conversion apparatus according to an embodiment of the invention is described in detail with reference to the accompanying drawings.

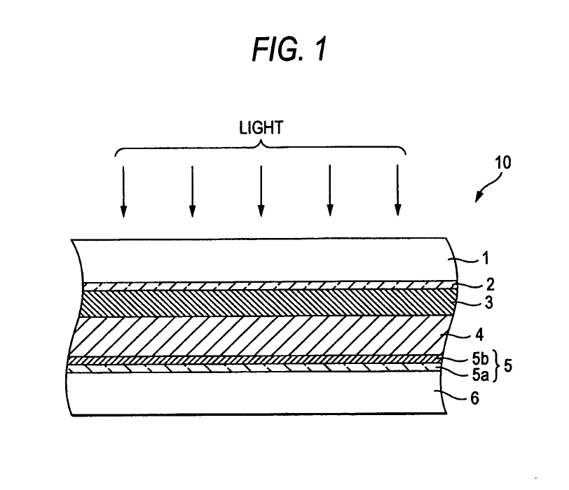

FIG. 1 is a cross-sectional view of a major portion of a configuration of a dye-sensitized photoelectric conversion apparatus 10 according to an embodiment of the present invention. The dye-sensitized photoelectric conversion apparatus 10 is configured by mainly containing a transparent substrate 1 such as glass, a transparent electrode (negative electrode) 2 containing a transparent conductive layer of, for example, FTO (fluorine-doped tin oxide (IV) SnO₂), a semiconductor layer 3 retaining a photosensitizing dye, an electrolyte layer 4 in a gel state, a counter electrode (positive electrode) 5, a counter substrate 6, and a sealing material (not shown) and the like.

As for the semiconductor layer 3, a porous article layer prepared by sintering fine particles of titanium oxide TiO₂ is used in many cases. On surfaces of the fine particles of titanium oxide TiO₂ which are contained in the semiconductor layer 3, a photosensitizing dye is retained. The electrolyte layer 4 in a gel state is provided between the semiconductor layer 3 and the counter electrode 5 and, for example, an organic electrolyte solution containing oxidation-reduction species (redox pair) such as I⁻/I₃⁻ is contained in the electrolyte layer 4. The counter electrode 5, which is made of a platinum layer 5b or the like, is formed on the counter substrate 6.

Although the electrolyte layer 4 in a gel state contained by the dye-sensitized photoelectric conversion apparatus 10 is one type of nanocomposite gel, since the matrix material thereof is in a fibrous state and has a large specific surface area, it has an extremely high performance in retaining the electrolyte. Therefore, the electrolyte can be gelled with a small addition thereof. As a result, in the gelled electrolyte in the past, a ratio of the matrix material which is electrochemically inactive in the gel is 20% by weight or more, while, according to an embodiment of the invention, the ratio of the matrix material is allowed to be decreased and an increase of the inner resistance is allowed to be suppressed and, accordingly, it becomes possible to suppress a decrease of the fill factor.

According to an embodiment of the invention, as the inorganic matrix material, such matrix material as obtained by subjecting the fine particles of the metal oxide to the hydrothermal reaction treatment in an aqueous strong alkali solution having a pH value of 10 or more is preferably used. The fine particles of the metal oxide are changed into fibrous state by the hydrothermal reaction treatment and, then, specific surface areas thereof are increased by 100 times. By this increase of the specific surface areas, a performance of retaining the electrolyte solution is enhanced and, then, the electrolyte solution can be gelled even with a small addition thereof.

Further, as the fine particles of the metal oxide to be subjected to the hydrothermal reaction treatment, titanium oxide is preferably used. A fibrous compound (hereinafter, referred to also as “titanium oxide-type nanowire”) to be obtained by subjecting titanium oxide to the hydrothermal reaction treatment is chemically stable, has a large specific surface area and, accordingly, is favorable as the inorganic matrix material. A primary particle size of the fine particles of titanium oxide is preferably in the range of from about 1 nm to about 500 nm. Among other things, those having a small size of from about several nm to about 100 nm are high in a ratio of conversion into a wire and are, therefore, favorable also from productivity. As for the fine particles of titanium oxide, it is possible to use, for example, commercially available ultrafine particles of titanium oxide or titanium oxide for a photocatalyst.

The hydrothermal reaction treatment in an aqueous strong alkali solution is preferably performed in an aqueous strong alkali solution containing at least one alkali selected from the group consisting of LiOH, NaOH, and KOH. By using any one of these alkali metal hydroxides, a fibrous titanium oxide-type nanowire having a large specific surface area can be obtained. A pH value of the aqueous strong alkali solution is preferably 10 or more and, from the standpoint of a reaction speed and productivity, the pH value is particularly preferably 13 or more.

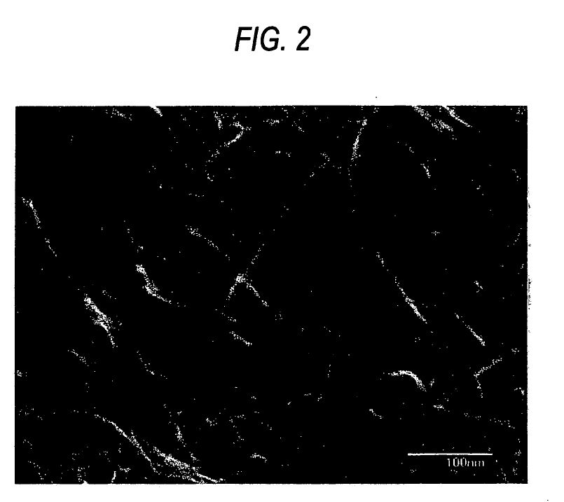

FIG. 2 is a scanning electron micrograph (SEM) of titanium oxide-type nanowire obtained in such manner as described above. It is observed that a plurality of elongated fibrous titanium oxide-type nanowires are three-dimensionally intertwined with one another and a configuration having many spaces is formed. The electrolyte is caught in these spaces and the electrolyte solution is gelled.

In the dye-sensitized photoelectric conversion apparatus according to the present embodiment, iodide salts including an iodide salt of an alkali metal and an iodide salt of a quaternary ammonium ion and iodine are dissolved in a non-aqueous solvent or an ionic solution as electrolytes such that an entire amount of substance (entire mol number) of the iodide salt comes to be from 1 to 50 times the amount of substance (mol number) of iodine and the resultant solution is used.

Iodide ions I⁻ ions are supplied from the iodide salt of the alkali metal and the iodide salt of the quaternary ammonium ion and a portion thereof reacts with iodine, to thereby generate a triiodide ion I₃⁻. In the electrolyte in the dye-sensitized conversion apparatus, charges are transferred by displacing these ions through diffusion, or by exchanging charges through an exchange reaction; however, since I₃⁻ has a large ion diameter, a diffusion speed thereof is slow than that of I⁻ and, therefore, it is necessary to smoothly supply the I₃⁻ ion by allowing a concentration of the I⁻ ion to be equal to or larger than that of I₃⁻.

On this occasion, an entire amount of substance (entire mol number) of the iodide salt is preferably from 1 to 50 times and, more preferably, from 2 to 30 times the amount of substance (mol number) of iodine. In addition, it is preferable that the mol concentration of the iodide salt of the quaternary ammonium ion is from 1 to 30 times that of iodine and the mol concentration of the iodide of the alkali metal is from 0.1 to 10 times that of iodine.

Specifically, the entire concentration of the iodide salt, namely, the mol concentration of the I⁻ ion is preferably from 0.5 to 3.0 mol/L and, more preferably, from 0.8 to 2.0 mol/L. Further, the iodine concentration is preferably from 0.01 to 0.5 mol/L and, more preferably, from 0.05 to 0.2 mol/L.

Examples of solvents contained in the electrolyte may include, but are not limited to, water, alcohols, ethers, esters, carbonic acid esters, lactones, carboxylic acid esters, phosphoric acid trimesters, heterocyclic compounds, nitrites, ketones, amides, nitromethane, a halogenated hydrocarbon, dimethyl sulfoxide, sulfolane, N-methyl pyrrolidone, 1,3-dimethyl imidazolidinone, 3-methyl oxazolidinone, and hydrocarbons. These solvents can be used singly or in combinations of two or more kinds. Among all, nitile-type, lactone-type, carbonate-type non-aqueous solvents are particularly preferable. Further, it is possible to use an ionic solution at room temperature of tetraalkyl-type, pyridinium-type, or imidazolium-type quaternary ammonium salt.

The dye-sensitized photoelectric conversion apparatus 10 is same as the dye-sensitized photoelectric conversion apparatus 100 in related art except that the gelled electrolyte layer 4 is used as an electrolyte layer and, when light is incident on the apparatus, it operates as a cell in which the counter electrode 5 is a positive electrode and the transparent electrode (transparent conductive layer) 2 is a negative electrode. A theory of such operation is as described below.

When the photosensitizing dye absorbs a photon which passes through the transparent substrate 1 and the transparent electrode 2, an electron inside the photosensitizing dye is excited to undergo transition from a ground state (HOMO) to an excited state (LUMO). The electron in the excited state is drawn out into a conduction band of the semiconductor layer 3 via an electric bond between the photosensitizing dye and the semiconductor layer 3, passes through the semiconductor layer 3 and, then, reaches the transparent electrode 2.

On the other hand, the photosensitizing dye which has lost the electron receives an electron from a reducing agent, for example, I⁻, in the electrolyte layer 4 in a gel state in accordance with the following reaction and, accordingly, generates an oxidizing agent, for example, I₃⁻, in the electrolyte layer 4 in a gel state:

2I⁻→I₂+2e⁻

I₂+I⁻→I₃⁻

The thus-generated oxidizing agent reaches the counter electrode 5 by diffusion and, then, receives an electron from the counter electrode 5 in accordance with the following reaction which is reverse to the above-described reaction and is, accordingly, reduced to an original reducing agent:

I₃⁻→I₂+I⁻

I₂+2e⁻→2I⁻

The electron which is sent out from the transparent electrode 2 to an outside circuit performs an electric work in the outside circuit and, then, returns to the counter electrode 5. In such a manner as described above, light energy is converted into electric energy without leaving any change in each of the photosensitizing dye and the electrolyte layer 4.

Although other members than the electrolyte layer 4 in a gel state are same as those of the dye-sensitized photoelectric conversion apparatus 100 in related art or the like, they are described in detail below.

The transparent substrate 1 is not particularly limited so long as it has such material quality and shape as permit light to easily pass therethrough and various types of materials can be used therefore and, on this occasion, a substrate material having a high transmittance against visible light is particularly preferred. Further, a material having a high blocking performance for preventing moisture and gas from intruding into the dye-sensitized photoelectric conversion apparatus 10 from outside and, also, having excellent solvent resistance and weather resistance is preferred. Examples of such substrates include transparent inorganic substrates of, such as, quartz, and glass; and transparent plastic substrates of, such as, polyethylene terephthalate, polyethylene naphthalate, polycarbonate, polystyrene, polyethylene, polypropylene, polyphenylene sulfide, polyvinylidene fluoride, acetyl cellulose, phenoxy bromide, aramids, polyimides, polystyrenes, polyarylates, polysulfones, and polyolefins. Thickness of the transparent substrate 1 is not particularly limited. The thickness may appropriately be determined by taking the light transmittance or performance of blocking an inside and an outside of the dye-sensitized photoelectric conversion apparatus 10 into consideration.

A transparent electrode (transparent conductive layer) 2 is formed on a surface of this transparent substrate 1 as an electron-drawing-out electrode (negative electrode). As resistance of the transparent electrode 2 is lower, the transparent electrode 2 is more favorable. More specifically, the resistance of the transparent electrode 2 is preferably 500 Ω/cm² or less and, more preferably, 100 Ω/cm² or less. As for the material forming the transparent electrode 2, known materials can be used. Examples of such materials include indium-tin complex oxide (ITO), fluorine-doped tin oxide (IV) SnO₂ (FTO), tin oxide (IV) SnO₂, zinc oxide (II) ZnO, and indium-zinc complex oxide (IZO). Usable materials are not limited to those examples, and two or more of them can be used in combination as well. The transparent electrode 2 is formed by a sputtering technique or the like.

Further, for the purpose of reducing the resistance of the electron-drawing-out passage, a pattern of wiring of a conductive material can be provided in contact with the transparent electrode 2. The conductive material is not particularly limited and it is desirable that it has high corrosion resistance and oxidation resistance and, also, leak current of the conductive material itself is low. Still further, even when the material has low corrosion resistance, it can be used by additionally providing a protective layer. Even still further, in order to protect this wiring from corrosion or the like, the wiring is preferably coated with a barrier layer.

As for the semiconductor layer 3, a porous film prepared by sintering fine particles of semiconductor material is used in many cases. As for the semiconductor material, not only an element semiconductor material represented by silicon, but also a compound semiconductor material, a material having a provskite structure and the like can be used. These semiconductor materials are each preferably an n-type semiconductor material in which a conduction-band electron becomes a carrier under light excitation and, then, generates an anode current. On this occasion, titanium oxide TiO₂, zinc oxide ZnO, tungsten oxide WO₃, niobium oxide Nb₂O₅, strontium titanate SrTiO₃, and tin oxide SnO₂ are specifically illustrated and, among all, anatase-type titanium oxide TiO₂ is particularly preferred. Further, types of semiconductor materials are not limited to those examples, and they can be used each singly or two or more of them can be used in combination or in complex form as well. Still further, semiconductor fine particles can take any one of various types of shapes such as a granular shape, a tube shape, and a rod shape, as need arises.

A method for making a film of the semiconductor layer 3 is not particularly limited and, when physical properties, convenience, production cost and the like are taken into consideration, a wet-type film making method is preferred and, on this occasion, a method in which, firstly, a dispersion in a paste state in which powder or sol of fine particles of the semiconductor is uniformly dispersed in a solvent such as water is prepared and, then, the thus-prepared dispersion is coated or printed on the transparent substrate 1 in which the transparent electrode layer 2 is formed is preferred. A coating method or a printing method is not particularly limited and can be conducted in accordance with a method in the related art. For example, as for such coating methods, a dip method, a spray method, a wire-bar method, a spin coat method, a roller coat method, a blade coat method, gravure method and the like can be used. Further, as for wet-type printing methods, a relief printing method, an offset printing method, a gravure printing method, an intaglio printing method, a rubber plate printing method, a screen printing method and the like can be used.

When titanium oxide is used, a crystal form thereof is preferably an anatase type which is excellent in a photocatalytic property. As for anatase-type titanium oxide, a commercial product in powder form, sol form or slurry form may be used, or that having a given particle diameter may be formed by a method in related art of, for example, hydrolyzing titanium oxide alkoxide. When commercially available powder is used, it is preferable to cancel a secondary aggregation and, at the time of preparing a dispersion in a paste state, it is preferable to crush particles by using a mortar or a ball mill. On this occasion, in order to prevent particles in which the secondary aggregation is cancelled from being aggregated again, any one of acetyl acetone, hydrochloric acid, a nitric acid, a surfactant, chelating agent and the like can be added to the dispersion in a paste state. Further, in order to increase viscosity of the dispersion in a paste state, any one of various types of thickeners such as a polymer such as polyethylene oxide or polyvinyl alcohol, or a cellulose-type thickener can be added to the dispersion in a paste state.

The particle diameter of the semiconductor fine particles is not particularly limited and is preferably from 1 to 200 nm and, more preferably from 5 to 100 nm in terms of an average particle diameter of primary particles. Further, it is possible to mix particles having a larger size than that of the semiconductor fine particles, to scatter incident light and, then, to enhance quantum yield. On this occasion, an average particle size of the particles to be mixed additionally is preferably from 20 to 500 nm.

As for the semiconductor layer 3, that having a large actual surface area including surfaces of fine particles facing pores inside porous film such that it can absorb the photosensitizing dye 4 in a large amount is preferred. For this account, the actual surface area in a state in which the semiconductor layer 3 is formed on the transparent electrode 2 is preferably 10 times or more and, more preferably, 100 times or more the area (projected area) of an outside surface of the semiconductor layer 3. There is no upper limit in such ratio as described above and the ratio is ordinarily about 1000 times.

Ordinarily, as the thickness of the semiconductor layer 3 is increased and, then, the number of fine particles of the semiconductor to be contained in the unit projected area is increased, the actual area is increased and the amount of the dye to be retained in the unit projected area is increased and, accordingly, light absorption is increased. On the other hand, when the thickness of the semiconductor layer 3 is increased, since a distance in which the electron which has transferred from the photosensitizing dye 4 to the semiconductor layer 3 is diffused until it reaches the transparent electrode 2 is increased, loss of electrons to be caused by reunion of charges inside the semiconductor layer 3 becomes large. Therefore, there exists an appropriate thickness of the semiconductor layer 3 and, ordinarily, the thickness thereof is, preferably, from 0.1 to 100 μm, more preferably from 1 to 50 μm and, particularly preferably, from 3 to 30 μm.

After the semiconductor layer 3 is prepared such that the semiconductor fine particles are coated or printed on the transparent electrode 2, the fine particles thereof are electrically connecting to each other, to thereby enhance mechanical strength of the semiconductor layer 3. Then, in order to enhance adhesion with the transparent electrode 2, the semiconductor layer 3 is preferably subjected to sintering. A range of a temperature of the sintering is not particularly limited. However, when the temperature is unduly high, electric resistance of the transparent electrode 2 becomes high and, further, the transparent electrode 2 may sometimes be melted and, therefore, ordinarily, it is, preferably, from 40 to 700° C. and, more preferably, from 40 to 650° C. Further, a time of the sintering is not particularly limited and, ordinarily, it is from about 10 minutes to about 10 hours.

After performing the sintering, for the purpose of increasing the surface area of the semiconductor fine particles or increasing necking between semiconductor fine particles, a dip treatment by, for example, an aqueous titanium tetrachloride solution or a sol of titanium oxide ultra-fine particles each having a diameter of 10 nm or less may be performed. When a plastic substrate is used as the transparent substrate 1 supporting the transparent electrode (transparent conductive layer) 2, it is also possible that the semiconductor layer 3 is made as a film on the transparent conductive layer 2 by using a paste dispersion containing a bonding agent and, then, boned to the transparent conductive layer 2 under pressure by using a hot press.

Photosensitizing dyes to be retained in the semiconductor layer 3 are not particularly limited, so long as they can exhibit a sensitizing action. Examples of the photosensitizing dyes include xanthene-type dyes such as rhodamine B, rose bengal, eosin and Erythrocin; cyanine-type dyes such as merocyanine, quinocyanine and cryptocyanine; basic dyes such as phenosafranine, Capri blue, thiocin and methylene blue; azo dyes; porphyrin-type compounds such as chlorophyll, zinc porphyrin and magnesium porphyrin; phthalocyanine-type compounds; coumarin-type compounds; ruthenium (Ru) bipyridine complexes; ruthenium (Ru) terpyridine complexes; anthraquinone-type dyes; polycyclic quinone-type dyes; and squarylium-type dyes. Among these dyes, the ruthenium (Ru) bipyridine complexes each having a pyridine cycle as a ligand are high in quantum yield and preferred as photosensitizing dyes. However, without being limited thereto, these dyes can be used alone or as a mixture of two or more kinds of them.

Methods for retaining the photosensitizing dyes in the semiconductor layer 3 are not particularly limited and, for example, any of the above-mentioned sensitizing dyes is dissolved in a solvent such as any one of alcohols, any one of nitrites, nitromethane, a halogenated hydrocarbon, any one of ethers, dimethyl sulfoxide, any one of amides, N-methylpyrrolidone, 1,3-dimethyl imidazolidinone, 3-methyl oxazolidinone, any one of esters, any one of carbonic acid esters, any one of ketones, a hydrocarbon, or water and, then, it is preferable that the semiconductor layer 3 is dipped in the resultant dye solution or the dye solution is applied on the semiconductor layer 3 to allow the semiconductor layer 3 to absorb the photosensitizing dye. Further, in order to reduce association of dyes among themselves, a deoxycholic acid or the like may be added to the dye solution.

For the purpose of removing excessively retained sensitizing dye, after the sensitizing dye is absorbed, a surface of the semiconductor layer 3 may be treated by using one of amines. Examples of the amines include pyridine, 4-tert-butyl pyridine, polyvinyl pyrrolidone, and imidazole-type compounds. When the amines are in liquid form, they may be used either as they are or after being dissolved each in an organic solvent.

As for a material for the counter electrode 5, any given material can be used, so long as it is a conductive material. It is also possible to use an insulating material, so long as a conductive layer is formed on the side, facing the electrolyte layer 4, of the insulating material. However, it is preferable to use a material which is electrochemically stable as the counter electrode 5 and, specifically, it is desirable to use platinum, gold, carbon, conductive polymers or the like.

Further, in order to enhance a catalytic action of the counter electrode 5 against a reduction reaction, it is preferable that a fine structure is formed on a surface of the counter electrode 5 which is in contact with the electrolyte layer 4 such that an actual surface area is increased and it is preferable that, for example, platinum is formed in a platinum black state and carbon is formed in a porous carbon state. Platinum black can be formed by treating platinum by an anodic oxidation method or by using chloroplatinic acid, while porous carbon can be formed by a method of sintering carbon fine particles or sintering an organic polymer or the like.

Since it is not necessary that the counter substrate 6 is transmittable to light, an opaque glass sheet, a plastic sheet, a ceramic sheet or a metal sheet may be used. Further, a transparent conductive layer is formed on a transparent counter electrode 5 and, then, a wiring is formed thereon by using a metal such as platinum which has a high redox catalytic action, or a surface thereof is treated with chloroplatinic acid and, then, can be utilized as a transparent counter electrode 5.

A method for producing the dye-sensitized photoelectric conversion apparatus 10 is not particularly limited. The electrolyte 4 in a gel state is applied on a surface of the semiconductor layer 3 containing the photosensitive dye by using a spatula or the like. When needed, the electrolyte solution is allowed to be infiltrated into the semiconductor layer 3 by using a vacuum deaerating.

In order to seal the dye-sensitized photoelectric conversion apparatus 10, the semiconductor layer 3 and the counter electrode 5 are placed opposing to each other with an appropriate space without allowing them to be in contact with each other and the substrate 1 and the counter substrate 6 are bonded to each other in a region in which the semiconductor 3 is not formed. A size of the space between the semiconductor layer 3 and the counter electrode 5 is not particularly limited and, ordinarily, it is, preferably, from 1 to 100 μm and, more preferably, from 1 to 50 μm. When the size of the space is unduly large, conductivity is lowered, to thereby reduce photocurrent.

Materials for such sealing materials are not particularly limited and those having light resistance, insulating properties, and moisture resistance are preferred. Examples of the materials to be usable include various types of epoxy resins, ultraviolet ray-curable resins, acrylic resins, polyisobutylene resins, EVA (ethylene-vinyl-acetate), ionomer resins, ceramics, glass frit, and various types of thermal fusion-bond resins.

Further, a deaerating port for eliminating excess amount of electrolyte or air-bubbles after such bonding as described above may be provided. A place in which the deaerating port is provided is not particularly limited, so long as it is not on the semiconductor layer 3 and on the counter electrode 5 opposing thereto.

After completely deaerated, the electrolyte remaining in the deaerating port is removed and, then, the deaerating port is sealed. A method for sealing the deaerating port is not particularly limited and it is possible, when needed, to seal the deaerating port by bonding a glass plate or a plastic substrate with a sealing material. It is preferable to perform the sealing by using a vacuum sealer under an inactive gas atmosphere or in a reduced pressure. After the sealing, it is possible to perform a heating or pressurizing operation, when need arises, such that the electrolyte solution of the electrolyte 4 can sufficiently be infiltrated into the semiconductor layer 3.

The dye-sensitized photoelectric conversion apparatus according to the embodiment of the invention can be produced in various types of shapes in accordance with applications and the shapes thereof are not particularly limited.

### EXAMPLES

Hereinafter, an embodiment according to the invention are described in detail with reference to drawings. However, the invention is not limited to these embodiments. In this embodiment, a dye-sensitized photoelectric conversion apparatus 10 as shown in FIG. 1 is prepared and, after measuring performances thereof such as a photoelectric conversion ratio, compared with that in Comparative Example.

### <Preparation of Dye-Sensitized Photoelectric Conversion Apparatus>

### Example 1

Ti-Nanoxide T (available from Solaronix SA) which is titanium oxide TiO₂ in a paste state was used as a raw material for forming a semiconductor layer 3. This TiO₂ paste was applied on an FTO layer which is a transparent electrode (transparent conductive layer) 2 on a transparent substrate 1 by using a blade coating method, to thereby produce a fine-particle layer in square having sizes of 5 mm×5 mm and a thickness of 200 μm. Then, after the layer was held for 30 minutes at 500° C., TiO₂ fine particles were sintered on the FTO layer 2, to thereby prepare a TiO₂ film. The thus-prepared TiO₂ film by such sintering was held in a 0.05M aqueous solution of titanium chloride (IV) TiCl₄ for 30 minutes under a temperature of 70° C., rinsed and, then, sintered again for 30 minutes at 500° C.

Thereafter, a treatment for enhancing the TiO₂ sintered body was performed such that ultraviolet light was irradiated on the semiconductor layer 3 (TiO₂ sintered body) for 30 minutes by using a UV (ultraviolet light) irradiating apparatus and, by this irradiation, impurities such as organic substances contained in the TiO₂ sintered body were removed by being oxidize-decomposed with a catalytic action of TiO₂.

Next, a cis-bis(isothiocyanate)-N,N-bis(2,2′-bipyridyl-4,4′-dicarboxylic acid)Ru(II)ditetrabutyl ammonium salt which is a photosensitizing dye was dissolved in a mixed solvent of tert-butyl alcohol and acetonitrile by 1:1 in volume such that the resultant solution had a concentration of 0.3 mM, to thereby prepare a photosensitizing dye solution. The semiconductor layer 3 was dipped in the thus-prepared photosensitizing dye solution for 24 hours at room temperature and the photosensitizing dye was allowed to be retained on a surface of the TiO₂ fine particles which configured the semiconductor layer 3. Next, after the semiconductor layer 3 was repeatedly rinsed with an acetonitrile solution of 4-tert-butyl pyridine and acetonitrile in this order, the solvent contained therein was evaporated in a dark place, to thereby dry the semiconductor layer 3.

On the other hand, in 2 g of methoxypropionitrile (MPN), sodium iodide NaI was dissolved in a concentration of 0.1 mol/L, 1-propyl-2,3-dimethylimidazolium iodide (DMPImI) in a concentration of 1.4 mol/L, iodine I₂ in a concentration of 0.15 mol/L, and 4-tert-butyl pyridine (TBP) in a concentration of 0.2 mol/L, to thereby prepare an electrolyte solution. This electrolyte solution was adjusted such that the mol number of iodide ion I⁻ became 10 times that of iodine I₂.

As for the raw material for the inorganic matrix material, titanium oxide powder (AMT-600; available from Tayca Corporation) was used. This powder was added to an aqueous solution of potassium hydroxide KOH having a concentration of 20 mol/L at a ratio of 1% by weight and allowed to be dispersed with an ultrasonic treatment. Next, the resultant dispersion was subjected to a hydrothermal reaction in an autoclave for 5 hours at 110° C., to thereby obtain a titanium oxide nanowire. The thus-obtained titanium oxide nanowire was thoroughly pickled in dilute hydrochloric acid and subjected to vacuum drying for removing moisture therefrom, to thereby obtain titanium oxide nanowire powder. The thus-obtained powder was added to the above-described electrolyte solution at a ratio of 10% by weight, and subjected to an ultrasonic treatment for one hour, to thereby allow it to be dispersed.

The thus-obtained electrolyte in a gel state was applied on a surface of the semiconductor layer 3 by using a spatula, to thereby form an electrolyte layer 4 in a gel state. The semiconductor layer 3 and the counter electrode 5 are placed opposing to each other with the electrolyte layer 4 in a gel state being interposed therebetween and, then, an outer periphery of the resultant configuration was sealed with an ultraviolet ray-curable resin mixed with insulating gap balls each having a size of 30 μm.

The counter electrode 5 was prepared such that a chromium layer having a thickness of 500 angstroms and a platinum layer 5b having a thickness of 1000 angstroms were laminated on an FTO layer 5a in the state order by using a sputtering method and, then, an isopropyl alcohol (2-propanol) solution of chloroplatinic acid was spray-coated on the resultant laminate and, thereafter, baked for 15 minutes at 385° C. and used.

### Comparative Examples 1 to 3

The dye-sensitized photoelectric conversion apparatuses were produced in a same manner as in Example 1 except for using materials shown in Table 1 as gelling agents. A mixing ratio (ratio based on an entire gel) of each of the gelling agents was set to be a minimum amount required for gelling.

TABLE 1

| | | Specific | Mixing ratio of |
|---|---|---|---|
| | | surface | gelling agent |
| | Gelling agent | area (m²/g) | (wt %) |
| Example 1 | Titanium oxide type | 500 | 10 |
| | nanowire | | |
| Comparative | Commercially available | 40 | 25 |
| Example 1 | titanium oxide powder P25 | | |
| Comparative | Carbon nanotube | 150 | 15 |
| Example 2 | | | |
| Comparative | PVdF (polymer gel type) | — | 20 |
| Example 3 | | | |
| Comparative | None | — | 0 |
| Example 4 | | | |

As to Example 1 and Comparative Examples 1 to 3, the electrolyte added with each gelling agent was put in a sample bottle and, then, the sample bottle was tilted at an angle of 90° to examine whether or not there was flowability therein and, then, such electrolyte as described above was confirmed with a naked eye that it had been gelled.

### <Performance Evaluation of Dye-Sensitized Photoelectric Conversion Apparatus>

As to dye-sensitized photoelectric conversion apparatuses in Example 1 and Comparative Examples 1 to 4 as produced in a manner as described above, a fill factor of a current-voltage curve and photoelectric conversion efficiency at the time of irradiating pseudo sunlight (AM: 1.5, 100 mW/cm²) were measured. The measurement results are shown in Table 2.

TABLE 2

| | | | Photoelectric |
|---|---|---|---|
| | Gelling agent | Fill factor | conversion efficiency |
| Example 1 | Present | 72.30% | 6.92% |
| Comparative | Present | 66.20% | 5.43% |
| Example 1 | | | |
| Comparative | Present | 68.10% | 5.81% |
| Example 2 | | | |
| Comparative | Present | 65.20% | 5.50% |
| Example 3 | | | |
| Comparative | Absent | 73.30% | 7.34% |
| Example 4 | | | |

As is apparent from Table 2, it has been found that the dye-sensitized photoelectric conversion apparatus in Example 1 of the invention has been remarkably improved in fill factors and the photoelectric conversion efficiency compared with the dye-sensitized photoelectric conversion apparatus in related art which used a nanocomposite gel or a polymer gel.

The photoelectric conversion apparatus according to the example of the invention can be utilized as, for example, a highly-safe dye-sensitized photoelectric conversion apparatus free from an anxiety that an electrolyte solution may be leaked and contributes to its distribution.

It should be understood by those skilled in the art that various modifications, combinations, sub-combinations and alterations may occur depending on design requirements and other factors insofar as they are within the scope of the appended claims or the equivalents thereof.

What is claimed is:

1. A photoelectric conversion apparatus, comprising:
an electrolyte layer interposed between a semiconductor layer and a counter electrode,
wherein the electrolyte layer includes an electrolyte retained in a fibrous inorganic matrix in a gel state.

2. A photoelectric conversion apparatus as set forth in claim 1, wherein the inorganic matrix comprises an inorganic matrix material obtained by subjecting fine particles of a metal oxide to a hydrothermal reaction treatment under a strong alkali having a pH value of 10 or more.

3. A photoelectric conversion apparatus as set forth in claim 2, wherein the metal oxide is titanium oxide.

4. A photoelectric conversion apparatus as set forth in claim 2, wherein the hydrothermal reaction treatment is conducted in an aqueous solution containing at least one type of a base selected from the group consisting of lithium hydroxide LiOH, sodium hydroxide NaOH, and potassium hydroxide KOH.

5. A photoelectric conversion apparatus as set forth in claim 1, which is configured as a dye-sensitized photoelectric conversion apparatus,
wherein a photosensitizing dye is retained in the semiconductor layer;
an electron of the photosensitizing dye excited by absorbing light is drawn out into the semiconductor layer; and
the photosensitizing dye which has lost the electron is reduced by a reducing agent in the electrolyte layer.

6. A gelling agent, comprising a fibrous inorganic matrix material.

7. A gelling agent as set forth in claim 6, wherein the inorganic matrix material comprises a crystalline nono-material.

8. A gelling agent as set forth in claim 7, wherein a composition of the inorganic matrix material is represented by the following general formula:
(M,H)ₓTi_{y}O_{z}
wherein M represents at least one alkali metal element selected from the group consisting of lithium Li, sodium Na, and potassium K; and
x, y, and z each represent a positive number.

9. A gelling agent as set forth in claim 8, wherein a diameter of the fibrous crystalline nano-material is in the range of from 2 to 80 nm.

10. A gelling agent as set forth in claim 8, wherein length of the fibrous crystalline nano-material is 100 nm or more.
